(19) United States
(12) Patent Application Publication
(10) Pub. No.: US 2012/0000607 A1
(43) Pub. Date: Jan. 5, 2012

(54) MASS FLOW CONTROL SYSTEM, PLASMA PROCESSING APPARATUS, AND FLOW CONTROL METHOD

(75) Inventors: Atsushi Ito, Mie (JP); Hideo Eto, Mie (JP)

(73) Assignee: Kabushiki Kaisha Toshiba, Tokyo (JP)

(21) Appl. No.: 13/173,286

(22) Filed: Jun. 30, 2011

(30) Foreign Application Priority Data
Jul. 1, 2010 (JP) 2010-151286

(51) Int. Cl. F16K 15/00; C23C 16/455; C23C 16/52; C23F 1/08

(52) U.S. Cl. 156/345.26; 137/467.5; 156/345.33; 118/723 R; 118/663

(57) ABSTRACT

A mass flow control system according to an embodiment includes a first mass flow controller that receives a corrosive gas having a corrosive effect on a predetermined material and has corrosion resistance to the corrosive gas, and a second mass flow controller that receives a non-corrosive gas having no corrosive effect on the predetermined material and is configured using the predetermined material. The mass flow control system further includes a plurality of first gas pipes that respectively supply a plurality of kinds of corrosive gases to the first mass flow controller, and a plurality of second gas pipes that respectively supply a plurality of kinds of non-corrosive gases to the second mass flow controller and are configured using the predetermined material.

### CROSS-REFERENCE TO RELATED APPLICATIONS

This application is based upon and claims the benefit of priority from the prior Japanese Patent Application No. 2010-151286, filed on Jul. 1, 2010; the entire contents of which are incorporated herein by reference.

### FIELD

Embodiments disclosed herein relate generally to a mass flow control system, a plasma processing apparatus, and a flow control method.

### BACKGROUND

In regard to controlling the flow rates of process gases used in semiconductor manufacturing processes, a technique has been proposed which organizes gas lines for a plurality of kinds of gases into a smaller number of systems than the kinds of gases, and provides a mass flow controller, which is a flow controller, per system.

However, some process gases used in the semiconductor manufacturing processes are corrosive. Therefore, pipes, the internal portions of the pipes, and gas passages in the mass flow controllers need to have corrosion resistance to such corrosive gases. There are known anticorrosion means such as selection of a pipe material and processing the internal portions of the pipes, and application of these means also need to depend on the kind of the corrosive gas.

### BRIEF DESCRIPTION OF THE DRAWINGS

FIG. 1 is a schematic diagram illustrating a configuration of a mass flow control system according to a first embodiment;

FIG. 2 is a schematic diagram illustrating a configuration of a plasma processing apparatus including the mass flow control system according to the first embodiment;

FIG. 3 is a diagram illustrating a configuration of a chamber in detail;

FIG. 4 is a schematic diagram illustrating a configuration of a mass flow control system according to a second embodiment;

FIG. 5 is a schematic diagram illustrating a configuration of a plasma processing apparatus including the mass flow control system according to the second embodiment; and

FIG. 6 is a schematic diagram illustrating a configuration of a plasma processing apparatus according to the related art.

### DETAILED DESCRIPTION

A mass flow control system according to an embodiment includes a first mass flow controller that receives a corrosive gas having a corrosive effect on a predetermined material and has corrosion resistance to the corrosive gas, and a second mass flow controller that receives a non-corrosive gas having no corrosive effect on the predetermined material and is configured using the predetermined material. The mass flow control system according to the embodiment further includes a plurality of first gas pipes that respectively supply a plurality of kinds of corrosive gases to the first mass flow controller, and a plurality of second gas pipes that respectively supply a plurality of kinds of non-corrosive gases to the second mass flow controller and are configured using the predetermined material.

Hereinafter, a mass flow control system, a plasma processing apparatus, and a flow control method according to embodiments will be described in detail with reference to the accompanying drawings. However, the present invention is not limited to the embodiments.

### First Embodiment

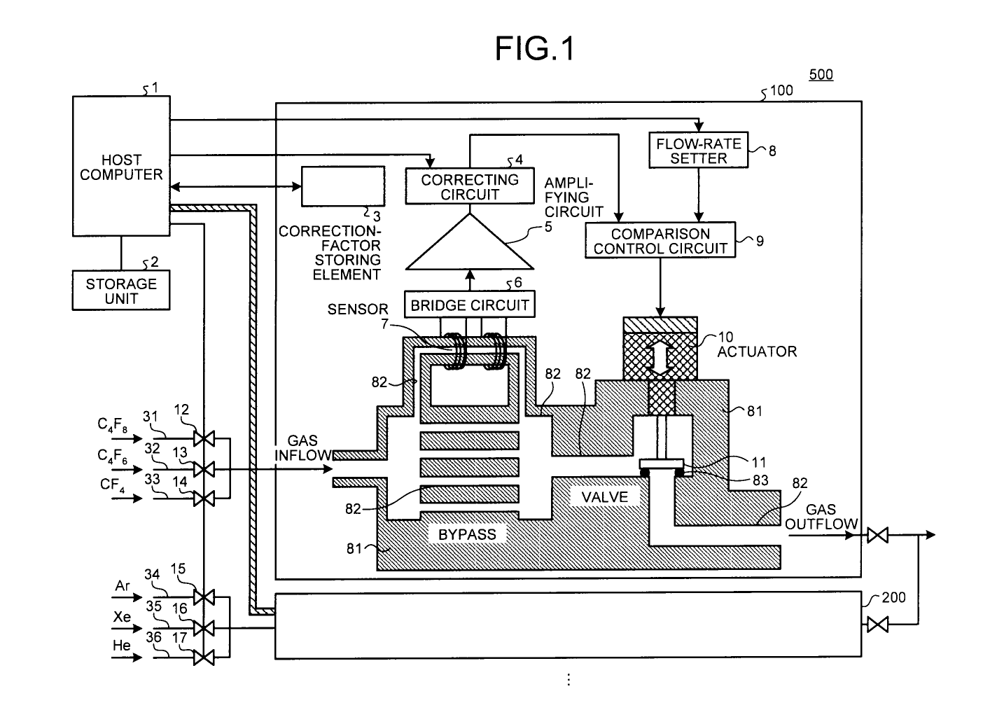

FIG. 1 is a schematic diagram illustrating a configuration of a mass flow control system 500 according to a first embodiment of the present invention. For example, the mass flow control system 500 includes a host computer 1, a storage unit 2 connected to the host computer 1 and storing a recipe (process program), a flow controller 100 controlled by the host computer 1 so as to control the flow rates of corrosive gases, and a flow controller 200 controlled by the host computer 1 so as to control the flow rates of non-corrosive gases.

The mass flow control system 500 further includes a valve 12 that controls a flow of C₄F₈ gas into the flow controller 100, a valve 13 that controls a flow of C₄F₆ gas into the flow controller 100, a valve 14 that controls a flow of CF₄ gas into the flow controller 100, a valve 15 that controls a flow of Ar gas into the flow controller 200, a valve 16 that controls a flow of Xe gas into the flow controller 200, and a valve 17 that controls a flow of He gas into the flow controller 200. These valves 12 to 17 are under control of the host computer 1.

Here, the flow controllers and pipe systems connected the flow controllers are separated in use, as a system for corrosive gases based on a carbon fluoride (CF) such as the C₄F₈ gas, the C₄F₆ gas, the CF₄ gas, and the like, and as a system for non-corrosive gases including inert gases such as the Ar gas, the Xe gas, the He gas, and the like. This is because the corrosive gases requires use of an expensive material (for example, SUS316L) for a pipe member 81 of the flow controller 100, coating (corrosion-resistant coating) on a pipe internal portion 82, surface polishing on the pipe internal portion 82, and use of a special corrosion-resistant gasket or O-ring 83 for pipe seal configured by using PTFE or the like so that a connection unit between the pipes may not be corroded. That is, the flow controller 100 is subjected to a corrosion-resistant process so as to endure the corrosive gases.

In order to enhance the corrosion resistance of the flow controller 100 against the corrosive gases, the pipe internal portion 82 may be electropolished. The electropolishing is a method of polishing a metal such as stainless, which is a material of the pipe member 81, while electrochemically dissolving the metal in an electrolyte, and can form a thin oxide film on the surface of the metal while planarizing the surface. Furthermore, a metal seal may be used in the connection unit similarly to improve the corrosion resistance.

In contrast, a pipe member of the flow controller 200 for non-corrosive gases uses, for example, SUS304, and the gasket or O-ring uses, for example, Viton. Therefore, the flow controller 100 for corrosive gases and the pipe system connected to the flow controller 100 incurs a manufacturing cost higher than that of the flow controller 200 for non-corrosive gases and the pipe system connected to the flow controller 200.

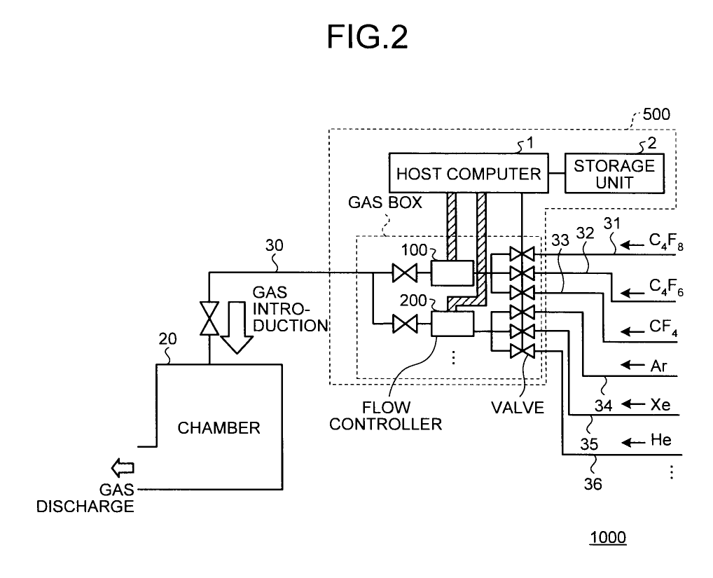

FIG. 2 is a schematic diagram illustrating a configuration of a plasma processing apparatus 1000 including the mass flow control system 500 according to the first embodiment. The plasma processing apparatus 1000 may be an RIE process apparatus, a CVD apparatus, or the like. The plasma processing apparatus 1000 can process a semiconductor substrate (wafer) introduced thereinto thereby to manufacture semiconductor devices.

The plasma processing apparatus 1000 includes a chamber 20 where a plasma process is performed, the mass flow control system 500 for controlling the flow rates of process gases introduced into the chamber 20 according to the above-mentioned recipe, a process gas pipe 30 for introducing the process gases from the mass flow control system 500 into the chamber 20, and a C₄F₈ gas pipe 31, a C₄F₆ gas pipe 32, a CF₄ gas pipe 33, an Ar gas pipe 34, a Xe gas pipe 35, and a He gas pipe 36 which are connected to the mass flow control system 500. In order to enhance the corrosion resistance, the insides of the C₄F₈ gas pipe 31, the C₄F₆ gas pipe 32, and the CF₄ gas pipe 33 may be electropolished.

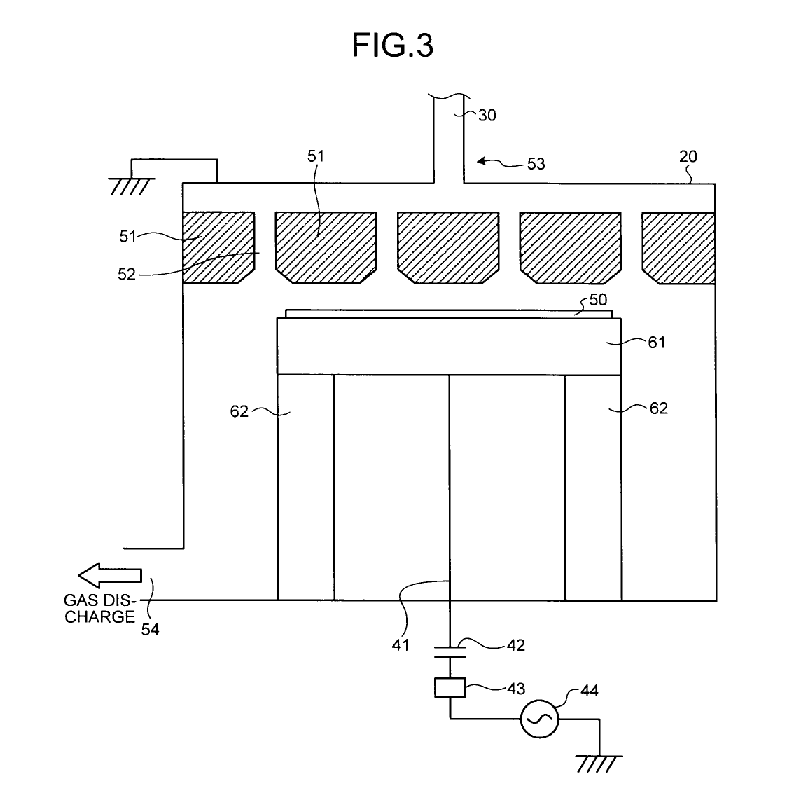

FIG. 3 is a diagram illustrating a configuration of the chamber 20 in more detail. The chamber 20 is airtightly configured, made of, for example, aluminum, and grounded. Inside the chamber 20, a support table 61 is provided to horizontally support a wafer 50 which is a process subject and to serve as a lower electrode. On the surface of the support table 61, a holding mechanism (not shown) such as an electrostatic chuck mechanism for electrostatically holding the wafer 50 is provided.

The support table 61 is supported on a cylindrical support unit 62 which vertically protrudes from the bottom, in the vicinity of the center, of the chamber 20, so as to be located in the vicinity of the center in the horizontal direction in the chamber 20. The support table 61 is connected to a power feeding line 41 for supplying high-frequency power, and the power feeding line 41 is connected to a blocking capacitor 42, a matching box 43, and a high-frequency power supply 44. The high-frequency power supply 44 supplies high-frequency power having a predetermined frequency to the support table 61.

Over the support table 61, a shower head 51 serving as an upper electrode is provided to face the support table 61 serving as the lower electrode. The shower head 51 is fixed to a side wall in the vicinity of an upper portion of the chamber 20 with keeping a predetermined distance from the support table 61, while facing and being in parallel to the support table 61. According to this configuration, the shower head 51 and the support table 61 form a pair of parallel plate electrodes. In the shower head 51, a plurality of gas supply passages 52 are formed to pass through a plate in a thickness direction.

In the vicinity of the upper portion of the chamber 20, a gas supply port 53 to which process gases to be used during a plasma process are supplied is provided. The gas supply port 53 is connected to the mass flow control system 500 shown in FIGS. 1 and 2 through the process gas pipe 30. In a lower portion of the chamber 20, a gas discharge port 54 is provided. The gas discharge port 54 is connected to a vacuum pump (not shown) through a pipe. With this configuration, a plasma process is performed in the chamber 20.

A brief overview of the plasma process in the chamber 20 configured as described above will be provided. First, the wafer 50, which is a process subject, is mounted on the support table 61, and is fixed by, for example, an electrostatic chuck mechanism. Next, the inside of the chamber 20 is vacuumed by the vacuum pump (not shown) connected to the gas discharge port 54. Then, if the inside of the chamber 20 reaches a predetermine pressure, the process gases are supplied to the gas supply port 53 through the process gas pipes 30 by the mass flow control system 500 shown in FIGS. 1 and 2, and is supplied toward the wafer 50 through the gas supply passages 52 of the shower head 51. If the inside of the chamber 20 reaches a predetermined pressure, a high-frequency voltage is applied to the support table 61 (lower electrode) while the shower head 51 (upper electrode) is kept grounded, so as to generate plasma in the chamber 20. Here, since the high-frequency voltage is applied to the lower electrode, a potential gradient is established between the plasma and the wafer 50 so that ions in the plasma can be accelerated toward the support table 61, whereby an etching process starts.

Specifically, according to the recipe (process program) stored in the storage unit 2, the process gases to be introduced into the chamber 20 are controlled by the mass flow control system 500. The recipe describes the kinds of gases and the flow rates of gases for each of steps performed time-sequentially. More specifically, even for the flow of the same kind of gas, it is possible to change the flow rate of the gas with time. However, for simplicity, the following description will be made on the assumption that, when the same gas flows, the flow rate of the gas is constant. However, the present invention is not limited to this recipe.

Here, the configuration of the flow controller 100 of the mass flow control system 500 shown in FIG. 1 will be described in more detail. If any one of the valves 12 to 14 is controlled so as to be opened by the host computer 1, one kind of gas flows from any one of the C₄F₈ gas pipe 31, the C₄F₆ gas pipe 32, and the CF₄ gas pipe 33 into the flow controller 100. The influent gas diverges to flow to a flow sensor side and a bypass side, and a predetermined proportion of the flow rate passes through a sensor 7. If the gas flows into the sensor 7, the temperature varies between an upstream resistive element and a downstream resistive element so that the balance of heat breaks and the temperature distribution of the sensor changes. This is detected by a bridge circuit 6, and is amplified and output as a flow-rate output signal (flow-rate signal voltage value) by an amplifying circuit 5.

Here, although the flow rates of gases into the flow controller 100 are the same, methods of removing heat from the gases differ between gases. Therefore, the flow-rate output signal represents different values depending on the properties of matter such as the mass and specific heat of the kind of the flowing gas. For this reason, in order to perform appropriate flow control, flow rate conversion for each gas is necessary, and it is necessary to correct the output signal of the amplifying circuit 5 with a correction factor (conversion factor: hereinafter, simply referred to as CF) depending on the kind of gas by a correcting circuit 4. The correction factor is a predetermined constant corresponding to the kind of each gas and is stored in a correction-factor storing element 3 in the flow controller 100, for example. Here, the CF (conversion factor) for each gas of the C₄F₈ gas, the C₄F₆ gas, and the CF₄ gas is stored.

In a case where the flow controller 100 is calibrated by N₂ gas, the flow rates of the other gases can be calculated by the following Equation. For example, in a case of the C₄F₈ gas, the correcting circuit 4 performs correction by the following Equation.

(Actual Flow Rate of C₄F₈ Gas)=(Flow-rate Output Signal of amplifying circuit 5)×{(CF of C₄F₈ Gas)/(CF of N₂ gas)}

In a case where the CF of another gas is calculated in advance by making the CF of the N₂ gas 1, correction can be performed only by the following Equation 1.

(Actual Flow Rate of C₄F₈ Gas)=(Flow-rate Output Signal of amplifying circuit 5)×(CF of C₄F₈ Gas) [Equation 1]

A comparison control circuit 9 compares the corrected flow-rate output signal value from the correcting circuit 4 with a flow-rate set signal value which is a desired flow rate for the corresponding gas set by a flow-rate setter 8, and operates an actuator 10 to control the flow rate by the valve 11 such that the corrected flow-rate output signal value matches with the flow-rate set signal value.

The internal configuration of the flow controller 200 for non-corrosive gases is basically the same as that of the flow controller 100, and thus it is not illustrated in detail in FIG. 1. However, since the non-corrosive inert gases such as the Ar gas, the Xe gas, and the He gas flow in the flow controller 200, the inside of the flow controller 200 and peripheral pipes do not need corrosion resistance, unlike the flow controller 100 for the corrosive gases and the pipe system connected thereto. A correction-factor storing element of the flow controller 200 stores the CFs for the Ar gas, the Xe gas, and the He gas. In the following discussion, it is assumed that the CFs for the other gases are determined in the flow controllers 100 and 200 by setting the CF for the N₂ gas to 1.

Hereinafter, a flow of an RIE process according to the recipe of the plasma processing apparatus 1000 will be described. Specifically, according to the recipe stored in the storage unit 2, the host computer 1 makes gases flow into the chamber 20 in each step of the recipe. For example, in a case where an instruction is described so that the C₄F₈ gas flows in the chamber 20 at a predetermined flow rate for a predetermined time period in a step of the recipe, the host computer 1 reads the CF of the C₄F₈ gas from the correction-factor storing element 3 of the flow controller 100 and sets the CF of the C₄F₈ gas to the correcting circuit 4. The correcting circuit 4 calculates the actual flow rate of the C₄F₈ gas according to the above-mentioned Equation 1. Further, the host computer 1 sets the predetermined flow rate described in the recipe to the flow-rate setter 8. At the same time, the host computer 1 opens the valve 12 fully, and feedback control is applied to the valve 11 by the comparison control circuit 9 such that the actual flow rate from the correcting circuit 4 matches with the predetermined flow rate. This control is performed for the predetermined time period.

Then, if the step finishes, according to an instruction for the next step, control as described above repeats. In a case where a gas flowing in the next step is a non-corrosive gas such as the Ar gas, control as described above is performed on the flow controller 200. In this way, the mass flow control system 500 can make the kinds of gases necessary for the RIE process in the chamber 20 flow in predetermined order at a predetermined rate for a predetermined time period.

In the first embodiment, when gas change is performed in each step in the process recipe (process program), a CF corresponding to the kind of gas stored in the correction-factor storing element 3 is read and the correction factor (CF) used in the correcting circuit 4 is automatically changed. Further, in the first embodiment, the correction-factor storing elements 3 storing the CFs corresponding to the kinds of gases are provided in the flow controllers 100 and 200. However, the CFs for all kinds of gases may be stored in the storage unit 2 or may be stored in a storage unit provided in another place.

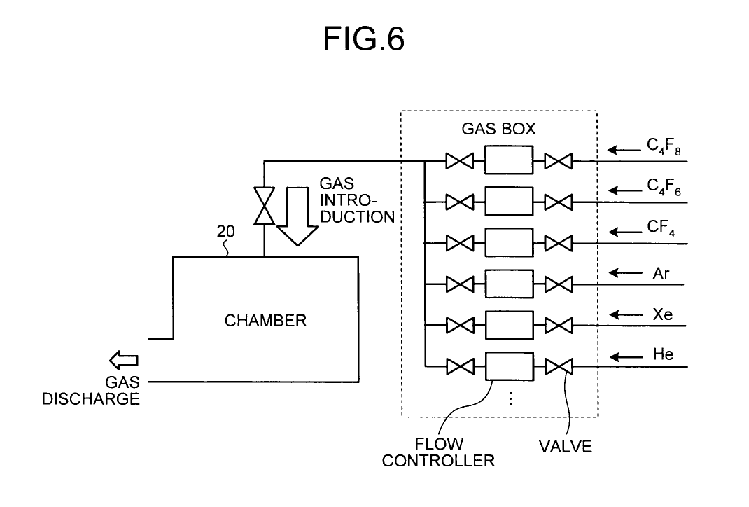

In the first embodiment, it is necessary only to separately provide flow controllers for corrosive gases and for non-corrosive gases while maintaining corrosion resistance to the corrosive gases. Accordingly, it is possible to considerably reduce the number of flow controllers as compared to a plasma processing apparatus according to the related art shown in FIG. 6 in which flow controllers are provided for every kind of gas in the gas box. Further, since it is possible to reduce the size of the gas box, it is possible to dispose the gas box near the chamber 20 by space saving. Accordingly, it is possible to shorten the pipe from the gas box to the chamber 20. Therefore, it is possible to further stabilizing the process performance and reduce cost and time for purging the remaining gases, thereby improving the productivity of the plasma processing apparatus.

### Second Embodiment

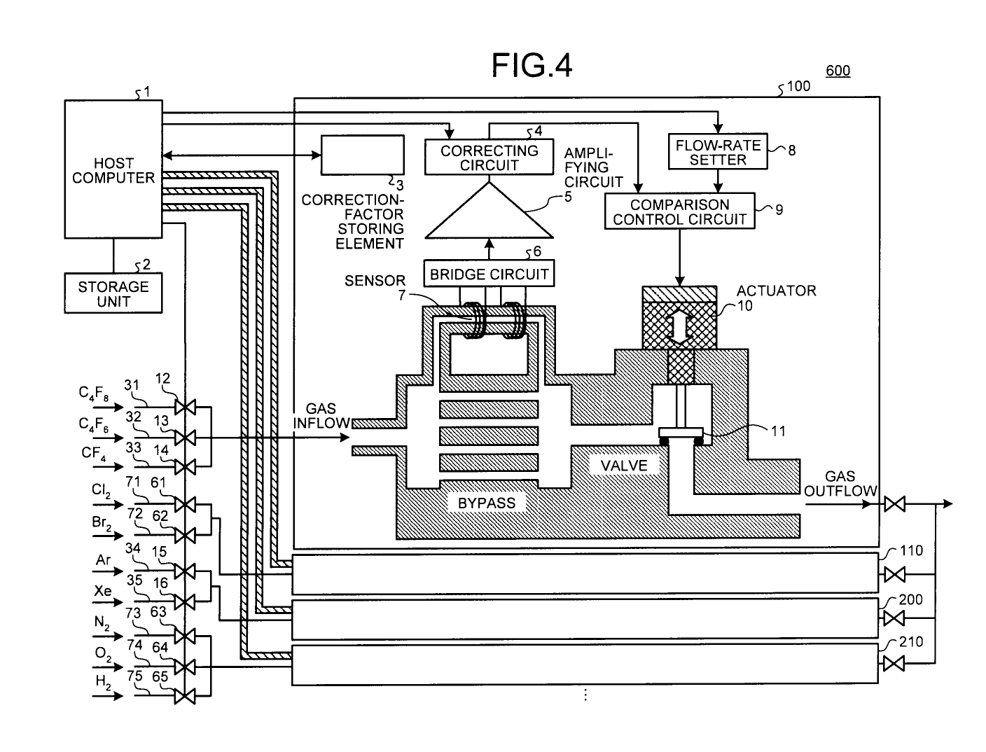

FIG. 4 is a schematic view illustrating a configuration of a mass flow control system 600 according to a second embodiment of the present invention. For example, the mass flow control system 600 includes a host computer 1, a storage unit 2 connected to the host computer 1 and storing a recipe (process program), a flow controller 100 controlled to control the flow rates of CF-based (carbon-fluoride-based) corrosive gases by the host computer 1, a flow controller 110 controlled to control the flow rates of corrosive halogen gases by the host computer 1, a flow controller 200 controlled to control the flow rates of non-corrosive inert gases by the host computer 1, and a flow controller 210 controlled to control the flow rates of non-corrosive general gases by the host computer 1.

The mass flow control system 600 further includes a valve 12 for controlling a flow of C₄F₈ gas into the flow controller 100, a valve 13 for controlling a flow of C₄F₆ gas into the flow controller 100, a valve 14 for controlling a flow of CF₄ gas into the flow controller 100, a valve 61 for controlling a flow of Cl₂ gas into the flow controller 110, a valve 62 for controlling a flow of Br₂ gas into the flow controller 110, a valve 15 for controlling a flow of Ar gas into the flow controller 200, a valve 16 for controlling a flow of Xe gas into the flow controller 200, a valve 63 for controlling a flow of N₂ gas into the flow controller 210, a valve 64 for controlling a flow of O₂ gas into the flow controller 210, and a valve 65 for controlling a flow of H₂ gas into the flow controller 210. These valves 12 to 16 and 61 to 65 are controlled by the host computer 1.

Here, the flow controllers and pipe systems connected to the flow controllers are separately used depending on gas. That is, they are classified as a system for CF-based (carbon-fluorine-based) corrosive gases such as C₄F₈ gas, the C₄F₆ gas, and CF₄ gas, a system for non-corrosive inert gases such as the Ar gas and Xe gas, a system for non-corrosive general gases such as N₂ gas, O₂ gas, and H₂ gas. This is because the corrosive gases need coating of a protective film on a pipe internal portion with an expensive material, surface polishing on the pipe internal portion, use of a connection unit having a special corrosion-resistant O-ring for pipe seal according to whether a corresponding system is a CF (carbon fluoride) system or a halogen system. That is, the flow controllers 100 and 110 and pipe systems connected thereto are subjected to corrosion resistance processes to the corrosive gases according to the CF (carbon fluoride) system and the halogen system, respectively.

In order to enhance the corrosion resistance of the flow controllers 100 and 110 for the corrosive gases, the pipe internal portions of the flow controllers 100 and 110 may be electropolished. The elestropolishing is a method of polishing a metal such as stainless, which is the pipe member, while electrochemically dissolving the metal in an electrolyte, and can form a thin oxide film on the surface of the metal while planarizing the surface. Also, in order to improve the corrosion resistance similarly, a metal seal may be used in the connection unit.

Therefore, the flow controllers 100 and 110 for the corrosive gases and the pipe systems connected thereto have a manufacture cost higher than the flow controllers 200 and 210 for the non-corrosive gases and the pipe systems connected thereto, as described with respect to the first embodiment.

Further, in the second embodiment, separate systems are used for non-corrosive inert gases and non-corrosive general gases. With respect to the H₂ gas which is a non-corrosive general gas, because of its explosive nature, in order to enhance airtightness, yet another system may be used.

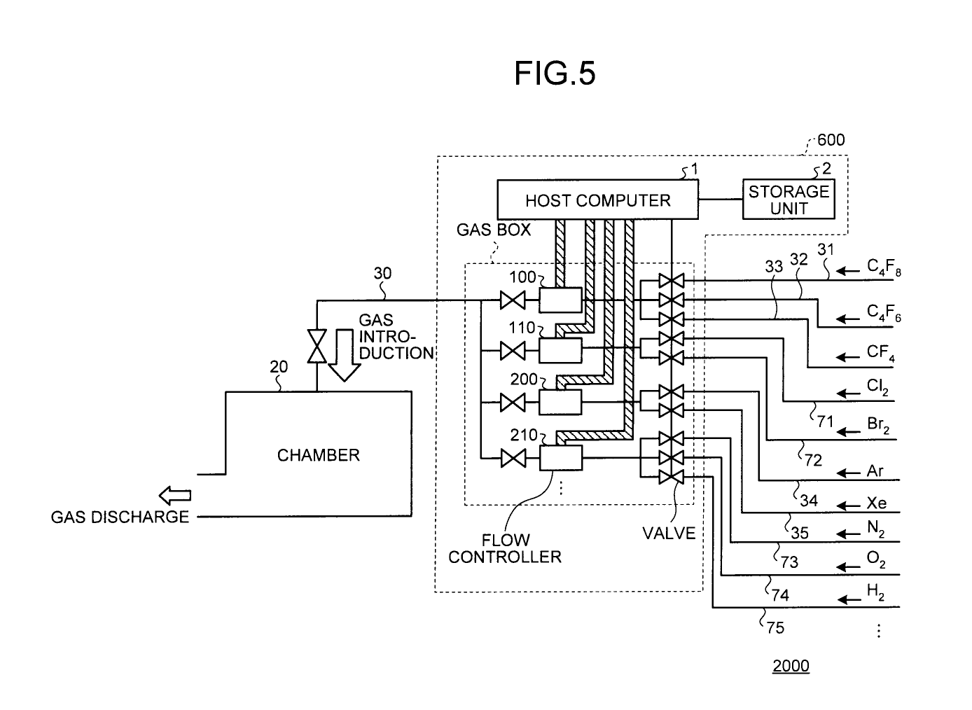

FIG. 5 is a schematic view illustrating a configuration of a plasma processing apparatus 2000 including the mass flow control system 600 according to the second embodiment. The plasma processing apparatus 2000 may be an RIE process apparatus, a CVD apparatus, or the like. The plasma processing apparatus 2000 can process a semiconductor substrate (wafer) introduced thereinto, so as to manufacture semiconductor devices.

The plasma processing apparatus 2000 includes a chamber 20 where a plasma process is performed, the mass flow control system 600 for controlling the flow rates of process gases into the chamber 20 according to the above-mentioned recipe, a process gas pipe 30 for introducing the process gases from the mass flow control system 600 into the chamber 20, and a C₄F₈ gas pipe 31, a C₄F₆ gas pipe 32, a CF₄ gas pipe 33, a Cl₂ gas pipe 71, a Br₂ gas pipe 72, an Ar gas pipe 34, a Xe gas pipe 35, a N₂ gas pipe 73, a O₂ gas pipe 74, a H₂ gas pipe 75, and the like which are connected to the mass flow control system 600. In order to improve the corrosion resistance, the insides of the C₄F₈ gas pipe 31, the C₄F₆ gas pipe 32, the CF₄ gas pipe 33, the Cl₂ gas pipe 71, and the Br₂ gas pipe 72 may be electropolished.

The configuration of the chamber 20 is the same as that shown in FIG. 3, and a procedure in which the process gases to be introduced into the chamber 20 are controlled by the mass flow control system 600 and an RIE process is performed according to the recipe (process program) stored in the storage unit 2 also is the same as the first embodiment, except that the number of mass flow controllers increases according to the categories of gases.

Even in the second embodiment, a correction-factor storing element 3 for storing a CF corresponding to the gas kind may be provided in the flow controllers 100, 110, 200, and 210 for each of the categories of gases. Alternatively, the CFs for all kinds of gases may be stored in the storage unit 2 or may be stored in a storage unit provided in another place.

Even in the second embodiment, it is necessary only to separately provide flow controllers for corrosive-gases and for non-corrosive gases while maintaining corrosion resistance. Accordingly, it is possible to considerably reduce the number of flow controllers as compared to the plasma processing apparatus according to the related art. Further, it is possible to select an optimal corrosion-resistant material according to a difference in corrosive nature between carbon-fluoride-based gases and halogen gases, and to reduce the cost.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A mass flow control system comprising:
a first mass flow controller that receives a corrosive gas having a corrosive effect on a predetermined material and has corrosion resistance to the corrosive gas;
a second mass flow controller that receives a non-corrosive gas having no corrosive effect on the predetermined material and is configured using the predetermined material;
a plurality of first gas pipes that respectively supply a plurality of kinds of corrosive gases to the first mass flow controller; and
a plurality of second gas pipes that respectively supply a plurality of kinds of non-corrosive gases to the second mass flow controller and are configured using the predetermined material.

2. The mass flow control system according to claim 1, wherein the first gas pipes have corrosion resistance to the corrosive gas.

3. The mass flow control system according to claim 1, wherein the first mass flow controller uses SUS316L or PTFE, or is electro-polished, so as to have the corrosion resistance to the corrosive gas.

4. The mass flow control system according to claim 2, wherein the first gas pipes use SUS316L or PTFE, or is electro-polished, so as to have the corrosion resistance to the corrosive gas.

5. The mass flow control system according to claim 2, wherein the second gas pipes do not have corrosion resistance to the corrosive gases.

6. The mass flow control system according to claim 1, wherein the corrosive gas includes a carbon-fluoride-based gas and a halogen gas, and the first mass flow controller includes a mass flow controller supplied with the carbon-fluoride-based gas and a mass flow controller supplied with the halogen gas.

7. The mass flow control system according to claim 2, wherein the corrosive gas includes a carbon-fluoride-based gas and a halogen gas, and the first mass flow controller includes a mass flow controller supplied with the carbon-fluoride-based gas and a mass flow controller supplied with the halogen gas.

8. The mass flow control system according to claim 1, wherein the second flow controller includes a mass flow controller supplied with an inert gas and a mass flow controller supplied with a non-corrosive gas.

9. The mass flow control system according to claim 6, wherein the second flow controller includes a mass flow controller supplied with an inert gas and a mass flow controller supplied with a non-corrosive gas.

10. The mass flow control system according to claim 1, wherein:
the corrosive gas include a carbon-fluoride-based gas and a halogen gas,
the plurality of first gas pipes have corrosion resistance to the corrosive gas,
the plurality of second gas pipes do not have corrosion resistance to the corrosive gas,
the first mass flow controller includes a mass flow controller supplied with a carbon-fluoride-based gas and a mass flow controller supplied with a halogen gas,
the second mass flow controller includes a mass flow controller supplied with an inert gases and a mass flow controller supplied with a non-corrosive gas,
the plurality of first gas pipes include a gas pipe that supplies the carbon-fluoride-based gas to the mass flow controller to be supplied with the carbon-fluoride based gas, and a gas pipe that supplies the halogen gas to the mass flow controller to be supplied with the halogen gas, and
the plurality of second gas pipes include a gas pipe that supplies the inert gas to the mass flow controller to be supplied with the inert gas, and a gas pipe that supplies the non-corrosive gas to the mass flow controller to be supplied with the non-corrosive gas.

11. The mass flow control system according to claim 10, wherein the first mass flow controller uses SUS316L or PTFE, or is electro-polished, so as to have the corrosion resistance to the corrosive gas.

12. The mass flow control system according to claim 1, wherein each of the mass flow controllers includes:
a flow-rate measuring unit that measures an input flow rate of a gas,
a correcting unit that corrects a measured result of the flow-rate measuring unit with a correction factor and outputs the corrected result as an output value,
a valve that adjusts a gas output flow rate, and
a valve control unit that controls the valve such that the output value of the correcting unit becomes equal to a predetermined flow-rate set value.

13. The mass flow control system according to claim 9, wherein each of the mass flow controllers includes:
a flow-rate measuring unit that measures an input flow rate of a gas,
a correcting unit that corrects a measured result of the flow-rate measuring unit with a correction factor and outputs the corrected result as an output value,
a valve that adjusts a gas output flow rate, and
a valve control unit that controls the valve such that the output value of the correcting unit becomes equal to a predetermined flow-rate set value.

14. The mass flow control system according to claim 10, wherein each of the mass flow controllers includes:
a flow-rate measuring unit that measures an input flow rate of a gas,
a correcting unit that corrects a measured result of the flow-rate measuring unit with a correction factor and outputs the corrected result as an output value,
a valve that adjusts a gas output flow rate, and
a valve control unit that controls the valve such that the output value of the correcting unit becomes equal to a predetermined flow-rate set value.

15. The mass flow control system according to claim 12, wherein the mass flow controller further includes a storage unit that stores the correction factor for each kind of gas.

16. The mass flow control system according to claim 14, wherein the mass flow controller further includes a storage unit that stores the correction factor for each kind of gas.

17. A plasma processing apparatus comprising:
a mass flow control system including a first flow controller that receives a corrosive gas having a corrosive effect on a predetermined material and has corrosion resistance to the corrosive gas, a second mass flow controller that receives a non-corrosive gas having no corrosive effect on the predetermined material by being configured using the predetermined material, a plurality of first gas pipes that respectively supply a plurality of kinds of corrosive gases to the first mass flow controller, and a plurality of second gas pipes that respectively supply a plurality of kinds of non-corrosive gases to the second mass flow controller, and
a chamber that performs a plasma process by using a gas supplied from the mass flow control system.

18. The plasma processing apparatus according to claim 17, wherein each of the mass flow controllers includes:
a flow-rate measuring unit that measures an input flow rate of a gas,
a correcting unit that corrects a measured result of the flow-rate measuring unit with a correction factor and output the corrected result as an output value,
a valve that adjusts a gas output flow rate, and
a valve control unit that controls the valve such that the output value of the correcting unit becomes equal to a predetermined flow-rate set value.

19. The plasma processing apparatus according to claim 18, further comprising a storage unit that stores the correction factor for each kind of gas.

20. A flow-rate control method of controlling flow rates of a plurality of different gases by using a plurality of mass flow controllers, the flow-rate control method comprising:
grouping the plurality of different gases into a first gas group including a plurality of different corrosive gases having a corrosive effect on a predetermined material and a second gas group including a plurality of different non-corrosive gases having no corrosive effect on the predetermined material; and
controlling the flow rates of the plurality of different gases using a first mass flow controller that is supplied with gases belonging to the first gas group including the plurality of different corrosive gases determined as a result of the grouping and that is configured to have corrosion resistance to the corrosive gases, and using a second mass flow controller that is supplied with gases belonging to the second gas group including the plurality of different non-corrosive gases determined as the result of the grouping and that is configured to use the predetermined material.
